(19) United States
(12) Patent Application Publication
(10) Pub. No.: US 2008/0186036 A1
(43) Pub. Date: Aug. 7, 2008

(54) High Speed Electrical Probe

(76) Inventor: Brian Shumaker, Carlos, CA (US)

Correspondence Address: LATHROP & GAGE LC, 4845 PEARL EAST CIRCLE, SUITE 300, BOULDER, CO, 80301, US

(21) Appl. No.: 11/671,792

(22) Filed: Feb. 6, 2007

(51) Int. Cl. G01R 1/067

(52) U.S. Cl. 324/754

(57) ABSTRACT

A high speed probe is configured with a diamond-gold plated tip to facilitate high speed test operations. A die is used to adjust the probe tips in a predetermined shape configuration.

### FIELD OF THE INVENTION

The field of the invention pertains to electrical probes for use in signal testing, such as determining signal integrity of high speed integrated circuits mounted on printed circuit boards, including microwave and integrated circuits.

### BACKGROUND

Probe devices for testing integrated circuits (IC's) are known in the art, and require reliable means for making a contact to the circuit that is to be tested, while at the same time causing minimal damage to the metal probe pads on the circuit. Early probe devices described in U.S. Pat. Nos. 4,697,143 and 4,827,211 did not have mechanically compliant contacting members and are no longer in general use because they did not male reliable contacts to the device under test (DUT). U.S. Pat. No. 4,871,964, U.S. Pat. No. 4,894,612 and U.S. Pat. No. 5,506,515 describe probes with mechanically resilient contacting members that allow much more reliable probing. Another structure provided by Ranieri et. al. (A Novel 24-GHz Bandwidth Coaxial Probe, IEIE Trans. Instr. and Meas., Vol. 39, No. 3, June, 1990) also describes mechanically resilient probe tips. These structures have better performance than the previous probes, but are somewhat difficult and costly to manufacture. In particular, during the soldering or brazing operation when the resilient tips are fastened to the probe body, it is difficult to assure the accurate placement of the contacting tips.

Another consideration is important when the high speed nature of the signals to be probed is considered. For fast signals, it is imperative that there is a minimum of probe tip length that separates the probed component lead and the working components within the probe proper, so as to minimize the introduction of stray inductance and stray capacitance. Often, the initial working component within a probe is an isolation or damping resistance, so that achieving a minimal probe tip length amounts to getting the isolation resistance, or other initial working component, relatively close to the location that is being probed. This is important, as it aids in observing with fidelity the (as probed) signal of interest as it occurs; and, it minimizes loading so that the signal as probed is essentially the same as it was before it was probed.

FIG. 1 shows a conventional time domain resistance (TDR) probe 100. The differential TDR probe 100 is made of two 50 ohm cables 102, 104 connected be solder 106. A probe tip area is formed by removing about ¼″ of the inner copper wire that is tined with solder that serve as probe tips 110, 112. FIG. 2 presents a cross sectional view taken along line 2-2′ of FIG. 1. This shows that in each of 50 ohm cables 102, 104, there are respective layers of copper shielding 114. 116 connected by solder 106. Insulation 118, 120 surrounds copper leads 122, 124 that communicate with the probe tips 110, 112. The probe tips 110, 112, are usually covered with a tined solder that oxidizes quickly and cannot easily penetrate through the copper surface oxide of a PCB trace.

Probe tip structures may be constructed from separate elements that are soldered or brazed together, or made from a single piece of material. Advantages of using a single piece of material include less expensive assembly, better control of connector dimensions and less susceptibility to connector damage during use. A structure that can be easily manufactured with close tolerances and still retain the resilient properties of the contacting connectors is advantageous.

Conventional TDR probes of the type shown as probe 100 cannot be used effectively to test circuitry operating generally in the gigahertz range, and such use is increasingly disadvantageous at speeds over 5 to 10 GHz. It would be a significant contribution to the art to provide high speed probes for use in testing high speed integrated circuits including circuit boards which are constructed of a single material.

### SUMMARY

The present invention provides high speed probes for use in testing high speed integrated circuits. The design taught herein vastly improves current differential probe technologies, which consist of soldering two independent 50 ohm semi-ridged or ridged cables together to create a 100 ohm TDR probe.

One embodiment includes a balanced multi mode 100 ohm differential time domain reflectometry (TDR) probe. This probe allows an engineer to inject and receive reflected differential TDR pulses onto printed circuit board (PCB) interconnects without use of a physical ground. Alternatively, a single probe tip may be used as a 100 ohm or 50 ohm probe to inject a pattern and another probe tip may measure responsive signal, for example, to study an injected fault through use of such commercially available equipment as the BertScope™ from Synthesis Research.

In one embodiment, the probe contains two components including: (1) a dual connector that may be a subminiature version A (SMA) connector with a, 1.85 mm, 2.92 mm. or 2.4 mm connector to accommodate different bandwidths beyond 30 GHz; and (2) a 3″ long twin axial semi-ridged cable. The twin axial cable center conductors are connected to the twin SMA connector. The cable contains a Teflon inner insulator material surrounding two center conductor's which measures 100 ohms impedance across them and 50 ohms impedance each to the outer case shield. The standard impedance across the two probe tips is a differential 100 ohm and the TDR signals do not need to reference the instrument's earth ground. Instead, a virtual ground is created between the plus and minus TDR signals. In the 50 ohm mode, a wire supplied with the probe connects one probe to the shield and a SMA shorting cap is attached to that probe's connector which connects with the TDR instrument ground.

The present instrumentalities further provide a method for using the high speed probes.

### BRIEF DESCRIPTION OF THE DRAWINGS

FIG. 1 shows a TDR probe of the prior art;

FIG. 2 is a cross-sectional view taken with respect to line 2-2′ of FIG. 1;

FIG. 3 shows one embodiment of a high speed test probe configured for use in TDR operations;

FIG. 4 is a cross-sectional view taken with respect to line 4-4′ of FIG. 3;

FIG. 5 provides additional detail with respect to a probe tip that is shown also in FIG. 3;

FIG. 6 provides additional detail with respect to a probe tip that is shown also in FIG. 5;

FIG. 7 shows a calibration tool that is used as a die to shape the probe tips;

FIG. 8 shows the probe of FIG. 3 in use as part of a probe system that includes a micromanipulator device and test electronics for compatible use with the probe;

FIG. 9 Shows a kit that contains a number of items for use with the probe;

FIG. 10 shows the probe with one tip shorted to present a 50 ohm system; and

FIG. 11 shows a 30 GHz waveform that was ascertained by use of the probe system that is described herein.

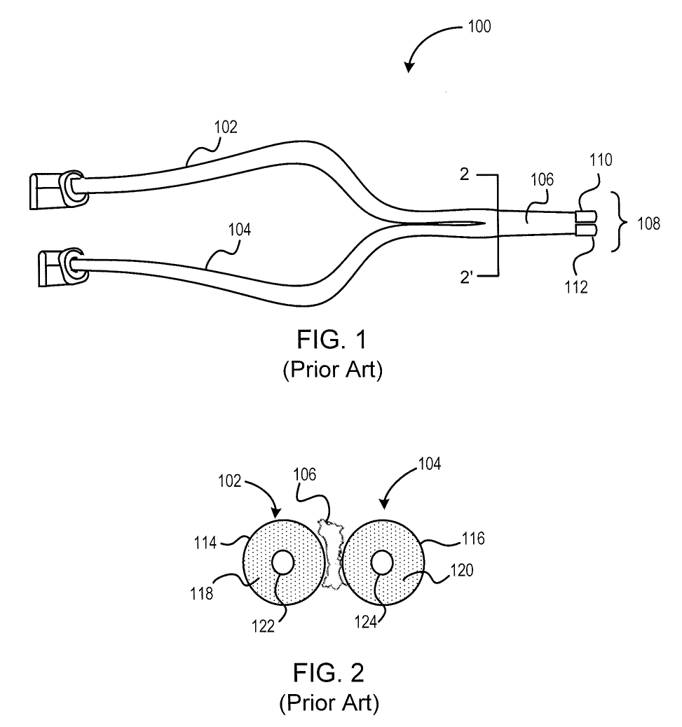

### DETAILED DESCRIPTION

There will now be shown and described a high speed probe for use in testing high speed circuits. As used herein, high speed circuits are rated to operate at 30 to 40 GHz or higher, although the probes described herein do not necessarily have to be used on these high speed circuits. Other suitable applications may be employed, so long as the high speed probe is compatible with the intended use.

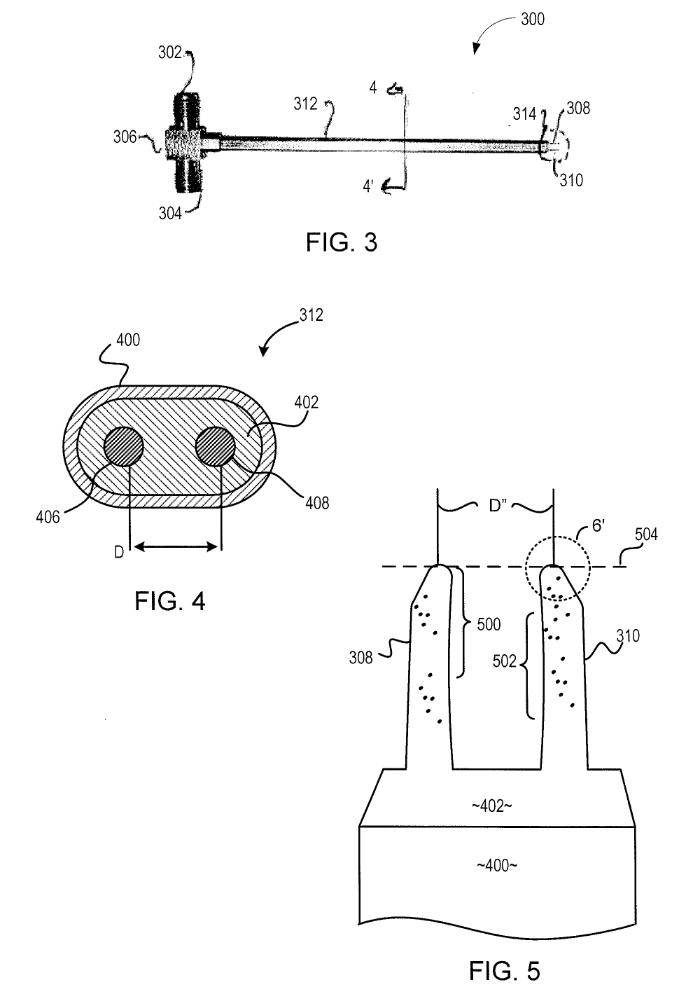

FIG. 3 shows a high speed probe 300. SMA connectors 302, 304 are mounted in block 306 for respective communications with probe tips 308, 310. a handle 312 contains conductors (not shown) respectively communicating the SMA connectors 302, 304 with corresponding probe tips 308 and 310. FIG. 4 is a cross sectional view taken along line 4-4′ of FIG. 3. An outer coating 400 may be a conductive form of Teflon® (PTFE) or another conductive material that is easy to clean. Insulation 406, 408 isolates conductor 406 from conductor 408. The conductors 406, 408 may be made of copper or another conductive metal, and a center-to-center separation distance of 0.056 inches works well for most testing applications. The conductors 406, 408 are connected in the standard way to SMA connectors 302, 304.

FIG. 5 provides additional detail with respect to the probe tip area 314 that is shown in FIG. 3. The probe tips 308, 310 may be provided with a diamond/gold plating 500, 502. This type of plating is generally available on commercial order and includes electroplated gold that is formed out of a solution in which there is diamond dust or powder. By way of example, a useful plating process is described in U.S. Pat. No. 4,079,052 issued to Fletcher. A gold-nickel solution, as it electroplates, bonds the diamond to the probe tips 308, 310. It will be further appreciated that the probe tips 308, 310 have bee adjusted by the use of a die such that the probe tips 308, 310 are separated by a predetermined distance D′. The use of this die also bends the probe tips 308, 310 into a planarized configuration relative to a line 504. running perpendicular to the elongate axis of conductors 4-02. 406 (shown in FIG. 4).

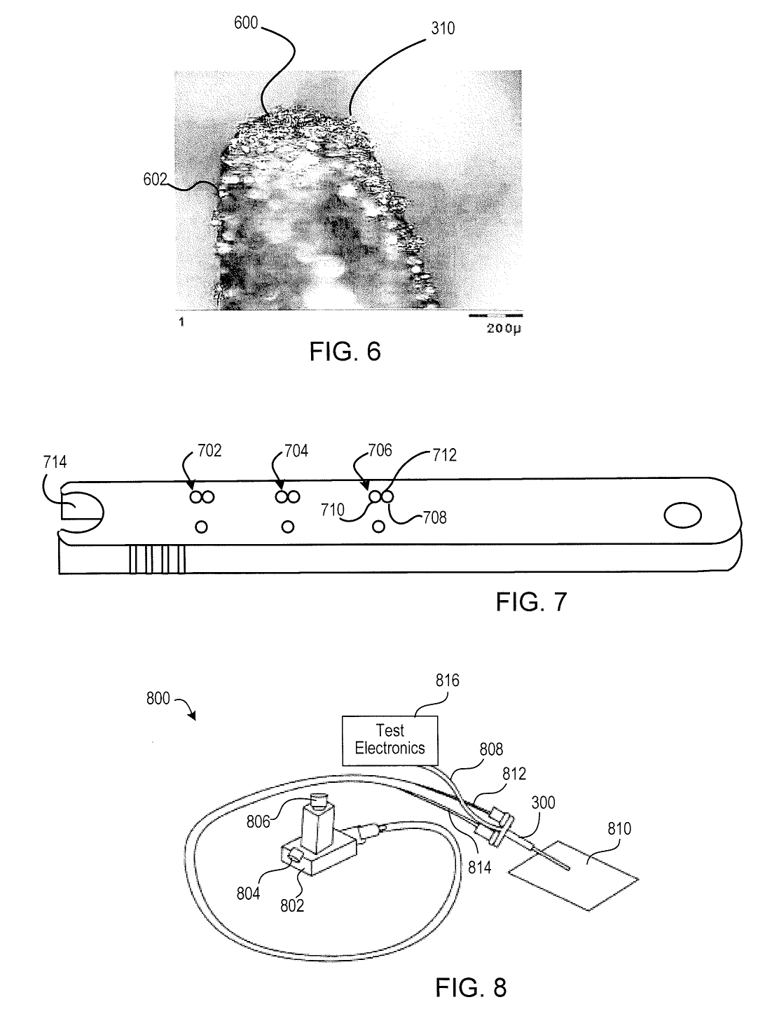

FIG. 6 shows a 121× enlarged photograph of a probe tip 310 corresponding to area 6′ of probe tip 310 in FIG. 5. Electrodeposition of gold occurs faster on smaller diameter, pointed surfaces. his is shown by an area of increasingly dense diamond coverage 600, as compared to off-tip surface 602. The gold advantageously prevents oxidation of the underlying connector, which is optionally copper, and the diamond powder provides a roughness that may be used to scratch though oxidation on a test article to facilitate use of the probe.

The diamond-gold plating process places hundreds of sharp diamonds in a nickel/gold solution on the very tips of the probes, with 1000's of diamonds on the overall probe surface. These gold-plated, conductive diamonds do not corrode and easily break though surface oxides and contaminants when probing. Probing force may be reduced to as little as 10 grams while creating a temporary connection as good as solder.

FIG. 7 depicts an elongate calibration tool 700 that contains receptacles 702, 704, 706, each including, for example, holes 708, 710 in the case of receptacle 706 separated by a dividing wall 712. The holes 708, 710 are machined to a depth of approximately one eighth of an inch and are locate don centers such that upon insertion of the probe tips 308, 310 (see FIG. 3) the holes 708, 710 cooperate with the dividing wall 712 to separate and panelize the probe tips on a pattern according to the foregoing discussion of FIG. 5. This pattern is determined by the structure of holes 710, 712, which act as a die to bend the probe tips 308, 310 into a predetermined shape configuration. As shown in FIG. 7, the receptacles 702, 704, 712 are provided to impart popular probe pitches for use in TDR testing, such as respective center offsets of 0.5 mm, 1 mm, and 2 mm center-to-center offsets in the dimension D′ (see FIG. 5). The calibration tool 700 also contains an SMA wrench 714 to facilitate the coupling of cables to probe 300.

FIG. 8 shows the probe 300 in a system 800 that includes a micromanipulator device 802. Internal gearing, such as worm gearing (not shown), is actuated by X-Y knob 804 and Y-Z knob 806 to move a holder 808 that is clamped or threadably attached to probe 300. The resulting range of motion permits selective positioning of probe 300 in contact with test article 810. Signals from this testing travel through cables 812, 814 to test electronics 816, which may be any type of system that is capable of using or analyzing the signals received from the use of probe 300. It is also possible to use probe 300 manually in these test operations.

As such, the probe 300 may be used as a TDR hand probe or mounted in a micromanipulator and operably coupled with commercially available TDR instruments from Tektronix, Agilent and/or Lecory to transfer a 100 ohm differential or 50 ohm single ended TDR pulses to be injected onto passive PCB interconnects, cables, sockets IC packages and interconnect systems like backplanes that contains many of the foresaid components to measure impedance, Roh and voltage. The TDR sends a TDR pulse thought the probe and the reflected signal returns thought the probe to the TDR instrument. The instrument graphs the incident and reflective TDR signal and vertically scales it in volts, Roh or impedance and in time or distance in the horizontal direction.

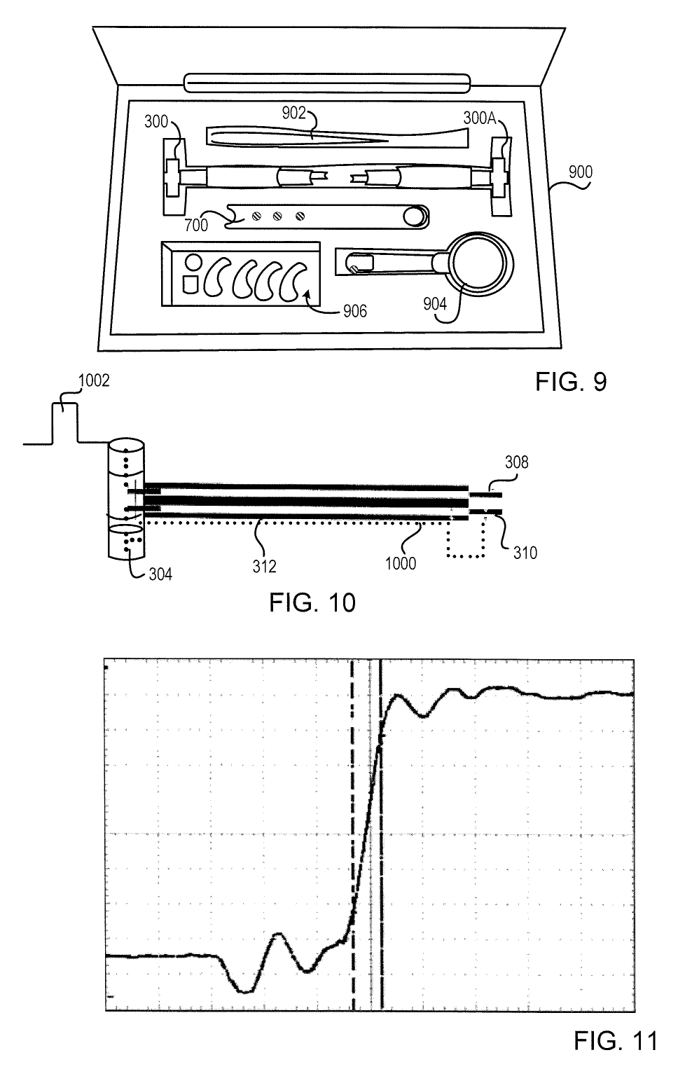

As shown in FIG. 9, the probe 300 may be provided in a bivalve case 900. The case 900 also contains a pair of tweezers 902, a magnifier 904, calibration tool 700, and a set of miscellaneous items 906 including gold foils, wire and shrink-wrap.

The probe 300 that is described above is configured for operating in a dual-TDR mode. The same probe may be configured to operate in single TDR mode by the application of one of gold foils 906. This is shown in FIG. 10 where a foil or any other conductor (not shown) is used to short probe tip 310 to the SMA ground on path 1000. Thus, only probe tip 308 is active on test pathway 1002. This is done, for example, by placing a foil between probe tip 310 and the conductive outer coating 312. It is also possible to establish ground path 1000 by running a wire (not shown) from probe tip 310 to SMA coupler 304. The wire may be retained in place by the use of shrink-wrap. Accordingly, probe 300 may be in a differential TDR or 100 ohm mode and probe 300A may be in a single tip or 50 ohm mode.

As is known in the art, a dual probe arrangement may be used to capture TDR/TDT waveforms. These signals may be used to determine what are known as s-parameters, eye diagrams, RLGG skin effect loss parameters, direct mutual and self L & C measurements and create accurate “measured based” Hspice, Berkeley or Pspice cable, backplane, IC package and connector models. FIG. 6 Demonstrates the TDR rise time performance that exceeds 30 GHz bandwidth. Application software to calculate these values is available on commercial order, for example, from Tektronix as their TDR and S-parameters software including IConnect and/or Measure Extractor™ packages.

One probe may be used to inject serial communication pulses into an active system and another probe measure the circuit variance or crossing points time jitter to produce an Eye diagram, for example, through use of the BertScope™ from Synthesis Research.

When used with a TDR Instrument, in the 100 ohm differential mode even and opposite pulses connected to the twin connector and the signals propagate down the twin axial cable to the probe tips. If both signals are start at the same time no physical ground is required. To operate the probe in the 50 ohm mode, a ground wire is connected to one of the probe tips and the probe shield. A shorting cap is attached to the grounded probe. The probe maintains a 100 ohm balanced transmission path creating a virtual ground. In the 50 ohm mode the probe's ground is referenced to the instruments ground.

FIG. 11 shows a differential rise time measurement that was obtained using the aforementioned [probe 300 connected to a Tektronix CSA 8200 50 GHz TDR sampling system driving a PSPL 4022 TDRT pulser. The measured bandwidth exceeds 30 GHz.

Those skilled in the art appreciate that the foregoing instrumentalities teach by way of example, and not by limitation. Accordingly, the what is claimed as the invention also encompasses insubstantial changes with respect to what is claimed. The inventor hereby states his intention to rely upon the Doctrine of Equivalents to protect the scope and spirit of the invention.

I claim:

1. A probe system comprising:
an elongate pair of conductors running substantially parallel to one through their length,
insulation that separates the conductors from one another;
the insulation being removed from one end of the pair of conductors to present a probe tip area having a pair of probe tips;
the probe tips being adjusted to a predetermined shape by the action of a die;
a pair of connectors each adapted to communicate with a corresponding one of the conductors from the pair of conductors, the pair of conductors being constructed and arranged to permit the attachment of cabling to the connectors for the conduct of test operations through use of the probe.

2. The probe system as set forth in claim 1, wherein the probe tip is plated with material including diamond and a noble metal.

3. The probe system as set forth in claim 1, further comprising the die formed as a body having a plurality of receptacles each including an arrangement of structure defining paired holes, the paired holes being constructed and arranged to separate the probe tips by a predetermined distance.

4. The probe system of claim 4, the paired holes being further constructed and arranged to planarize the probe tips for a predetermined angle of presentation of the probe tips to a test article.

5. The probe system of claim 1, further comprising a micromanipulator device configured to move the probe tips relative to a test article.

6. The probe system of claim 1, further comprising a conductive coating and means for shorting one of the probe tips to the conductive outer coating.

7. The probe system of claim 1 further including test electronics configured to perform test analysis by use of signals received from the probe tips.

8. The probe system of claim 1 wherein the test electronics are configured to perform test calculations on a signal cycle speed of at least ten GHz.

9. The probe system of claim 1 wherein the test electronics are configured to perform test calculations on a signal cycle speed of at least twenty GHz.

10. The probe system of clam 1 wherein the test electronics are configured to perform test calculations on a signal cycle speed of at least thirty GHz.

11. The probe system of claim 1 wherein the test electronics are configured to perform test calculations on a signal cycle speed of at least forty GHz.

12. The probe system of claim 1 wherein the test electronics are configured to perform test calculations on a signal cycle speed of at least fifty GHz.

13. A method of testing an electrical circuit through use of a probe system that contains
an elongate pair of conductors running substantially parallel to one through their length,
insulation that separates the conductors from one another;
the insulation being removed from one end of the pair of conductors to present a probe tip area having a pair of probe tips;
the probe tips being adjusted to a predetermined shape by the action of a die;
a pair of connectors each adapted to communicate with a corresponding one of the conductors from the pair of conductors, the pair of conductors being constructed and arranged to permit the attachment of cabling to the connectors for the conduct of test operations through use of the probe,
the method comprising the steps of:
adjusting the probe tips by the use of a die to impart a predetermined shape configuration thereto;
contacting an electrical circuit with the probe tip area;
receiving a signal from the probe tip area; and
performing an analysis of the signal to represent performance of the electrical circuit.

14. The method of claim 13, wherein the step of performing an analysis includes a performing a TDR analysis.

15. The method of claim 13 wherein the test electronics are configured to perform test calculations on a signal cycle speed of at least ten GHz.

16. The method of claim 13 wherein the test electronics are configured to perform test calculations on a signal cycle speed of at least twenty GHz.

17. The method of clam 13 wherein the test electronics are configured to perform test calculations on a signal cycle speed of at least thirty GHz.

18. The method of claim 13 wherein the test electronics are configured to perform test calculations on a signal cycle speed of at least forty GHz.

19. The method of claim 13 wherein the test electronics are configured to perform test calculations on a signal cycle speed of at least fifty GHz.

20. The method of claim 1 wherein the probe tips have a diamond-gold plating and the step of contacting includes using the diamond-gold plating to scratch though oxidation on the electrical circuit.
